(19) United States
(12) Patent Application Publication
(10) Pub. No.: US 2014/0117177 A1
(43) Pub. Date: May 1, 2014

(54) PORTABLE ELECTRONIC DEVICE RING-HOLDER

(71) Applicant: Sulumbek Shamsadov, Brooklyn, NY (US)

(72) Inventor: Sulumbek Shamsadov, Brooklyn, NY (US)

(21) Appl. No.: 14/063,876

(22) Filed: Oct. 25, 2013

Related U.S. Application Data
(60) Provisional application No. 61/795,820, filed on Oct. 25, 2012.

(51) Int. Cl. H05K 7/00

(52) U.S. Cl. CPC H05K 7/00
USPC 248/205.1; 29/428

(57) ABSTRACT

Embodiments disclosed herein provide systems and methods for a multifunction device holding accessory to improve the convenience of use of portable electronic devices. In embodiments, two half-rings may be configured to be positioned in a first position and in a second position. In the first position, the two half-rings may be configured to form a ring that is congruent with a body of the multifunction device holding accessory. In the second position, the two half-rings may be configured to project away from the body of the multifunction device holding accessory to form a ring-hook.

### CROSS-REFERENCE TO RELATED APPLICATIONS

This application claims a benefit of priority under 35 U.S.C. §119 to Provisional Application No. 61/795,820, filed on Oct. 25, 2012, entitled “PORTABLE ELECTRONIC DEVICE RING-HOLDER” which is fully incorporated by reference in its entirety.

### TECHNICAL FIELD

This disclosure relates generally to systems and methods for a portable electronic device holder. Specifically, this disclosure relates to systems and methods for a device holder with dynamic half-rings configured to form a ring-hook.

### BACKGROUND

Portable electronic devices are expensive and may include valuable and important data. These portable electronic devices rely on sensitive and fragile components, which may be damaged if the portable electronic device is dropped. If a component, such as a screen of the portable electronic device or the device's memory is broken, then the user may not be able to obtain the valuable and important data stored within the portable electronic device.

Conventionally, to secure portable electronic devices while moving, a user may place the portable electronic device in the user's pocket, purse, backpack, etc. However, if the portable electronic device is within their pocket, purse, backpack, etc. then the user may not be able to access it.

Alternatively, while walking the user may place the portable electronic device in their hand, and use the portable electronic device's interface to access the phone or other device. However, the user may accidentally drop the portable electronic device, which may damage it.

Accordingly, needs exists for improved and efficient methods and systems to securely hold and operate a portable electronic device.

### SUMMARY

Embodiments disclosed herein provide systems and methods for a multifunction accessory to improve the convenience of use of portable electronic devices.

Embodiments include a portable electronic device holder with a first and a second surface.

A new portable electronic device holder may have a body including a first surface, a second surface, and a periphery, where the first surface is configured to attach to a device (for example using a suction cup or other vacuum or mechanical fastener) and a first element and a second element.

Each of the first and second element may be attached to the body and configured to be disposed in a first position, in which the element is parallel with the body, and to be disposed in a second position, in which the element projects away from the second surface. The first element and second element may be configured, when both are in the second position, to form a closed path together with the body, wherein a finger can be inserted through the closed path to secure the finger to an attached device. Although in many embodiments the closed path may make a complete circuit with no gaps therein, the term is used in a broader sense herein, to include any circuit with no more than a finger's-width gap, such that a finger inserted therein cannot pass through any such gap. To accommodate individuals with smaller fingers, typically a gap of no more than ⅜″ may be used, and in some embodiments no more than ¼″.

In embodiments, a first end of the first element may be positioned adjacent to a second end of the second element and a first end of the second element may be positioned adjacent to a second end of the first element when the first and second elements are both in the first position.

The first end of the first element may be positioned adjacent to the first end of the second element when the first and second elements are both in the second position.

The first element and the second element may be configured to rotate away from the body to move from the first position to the second position.

The first end of the first element may be configured to couple with the first end of the second element in a position vertically aligned with a center of the body when the first and second elements are both in the second position.

The first end of the first element may include a first ferromagnetic material and the first end of the second element may include a second ferromagnetic material, such that the first ferromagnetic material and the second ferromagnetic material are attracted to each other. In other embodiments there may be other mechanisms for fixing (generally temporarily) the first and second elements in the second position. Such mechanisms may include mechanical or other fasteners connecting the first and second elements to each other in the second position, and/or stops or other elements to create friction when the elements are in the second position, tending to keep the elements in the second position unless force is applied with the intention of bringing the elements back into the first position.

The body may be circular and the first and second elements may be half-rings.

The first element may be configured to rotate in a first direction and the second element may be configured to rotate in a second direction when moving from the first position to the second position.

The first and second elements may extend, in the first position, along the periphery of the body, and may extend along the entire periphery of the body. Each of the first and second elements may extend, in the first position, halfway around the periphery of the body.

The closed path may have a curved inner edge such that, viewed straight through its central axis, the opening defined by the inner edge appears to be oval or elliptical. Such openings may be more comfortable for users' rounded fingers.

Each of the first and second elements may include a projection on one end to provide a frictious contact point by which the element can be moved from the first position to the second position.

The body may include a recess, where the first and second elements are in the recess when in the first position, thereby reducing the height the first and second elements extend above the body in the first position.

Swing limiters may prevent rotation of the first and second elements past the second position.

A new portable electronic device holder method may include the steps of attaching a portable electronic device holder to a device, moving first and second elements of the device from the first position to the second position and inserting one or more fingers through the closed path. Moving the first and second elements from the first position to the second position may entail manipulating one end of each of the first and second elements and rotating the first and second elements in opposite directions.

A new portable electronic device holder method may include the steps of providing a body including a first surface and a second surface and having a periphery, where the first surface is configured to attach to a device, attaching a first element and a second element to the body and configuring each element to be disposed in a first position, in which the element is parallel with the body, and to be disposed in a second position, in which the element projects away from the second surface, and configuring the first element and second element, when both are in the second position, to form a closed path together with the body, where a finger can be inserted through the closed path to secure the finger to an attached device. It may also include providing a recess in the body configured such that the first and second elements are in the recess when in the first position, thereby reducing a height the first and second elements extend above the body in the first position, and providing swing limiters on the body that prevent rotation of the first and second elements past the second position.

The first surface of the portable electronic device holder may include a vacuum device, or another fastener for attaching the holder to an electronic device. The vacuum device may be a device that uses negative pressure of air to create a vacuum or a partial vacuum to couple with or adhere to a surface or backing of a portable electronic device.

The second surface of the portable electronic device holder may include a ring-hook. The ring-hook may include two dynamic half-rings. The two half-rings may be configured to rotate in opposite directions to form a ring-hook. The ring-hook may have a substantially circular opening that may be configured to interface with a user's hand, such that the user may hold and operate the portable electronic device coupled to the vacuum device.

In embodiments, the two half-rings may be configured to be positioned in a first position and in a second position. In the first position, the two half-rings may be disposed within a channel positioned along a circumference of the portable electronic device holder, and the two half-rings may be configured to form a ring that is congruent with a body of the ring-hook.

In the second position, the two half-rings may be configured to project away from the body of the portable electronic device holder to form the ring-hook. In embodiments, if the two half-rings are in the second position, the half-rings may be configured to slide along a user's finger to different positions on the user's finger.

Embodiments disclosed herein may improve the comfort of a user while holding a portable electronic device, and the user may have confidence that the electronic device is secured to the vacuum device of the portable electronic device holder.

These, and other, aspects of the invention will be better appreciated and understood when considered in conjunction with the following description and the accompanying drawings. The following description, while indicating various embodiments of the invention and numerous specific details thereof, is given by way of illustration and not of limitation. Many substitutions, modifications, additions or rearrangements may be made within the scope of the invention, and the invention includes all such substitutions, modifications, additions or rearrangements.

### BRIEF DESCRIPTION OF THE DRAWINGS

Non-limiting and non-exhaustive embodiments of the present disclosure are described with reference to the following figures, wherein like reference numerals refer to like parts throughout the various views unless otherwise specified.

FIG. 1 depicts a portable electronic device holder, according to one embodiment.

FIG. 2 depicts a top view of portable electronic device holder, according to one embodiment.

FIG. 3 depicts a side view of a portable electronic device holder with a first half-ring and a second half-ring being in the first position, according to one embodiment.

FIG. 4 depicts a perspective view of a portable electronic device holder with a first half-ring and a second half-ring being in the second position, according to one embodiment.

FIG. 5 depicts a side view of a portable electronic device holder with a first half-ring and a second half-ring being in the second position, according to one embodiment.

FIG. 6 depicts a side view of a portable electronic device holder with a first half-ring and a second half-ring being disposed in a position between the first position and the second position, according to one embodiment.

FIG. 7 depicts a side view of a portable electronic device holder with a first half-ring and a second half-ring being in the second position, according to one embodiment.

FIG. 8 depicts a top view of a portable electronic device holder with a first half-ring and a second half-ring being in the second position, according to one embodiment.

FIG. 9 depicts an exploded view of a body of a portable electronic device holder, according to one embodiment.

FIG. 10 depicts a first half-ring, according to one embodiment.

### DETAILED DESCRIPTION

The invention and the various features and advantageous details thereof are explained more fully with reference to the nonlimiting embodiments that are illustrated in the accompanying drawings and detailed in the following description. Descriptions of well-known starting materials, processing techniques, components and equipment are omitted so as not to unnecessarily obscure the invention in detail. It should be understood, however, that the detailed description and the specific examples, while indicating preferred embodiments of the invention, are given by way of illustration only and not by way of limitation. Various substitutions, modifications, additions and/or rearrangements within the spirit and/or scope of the underlying inventive concept will become apparent to those skilled in the art from this disclosure.

As used herein, the terms “comprises,” “comprising,” “includes,” “including,” “has,” “having” or any other variation thereof, are intended to cover a non-exclusive inclusion. For example, a process, article, or apparatus that comprises a list of elements is not necessarily limited to only those elements but may include other elements not expressly listed or inherent to such process, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Additionally, any examples or illustrations given herein are not to be regarded in any way as restrictions on, limits to, or express definitions of, any term or terms with which they are utilized. Instead, these examples or illustrations are to be regarded as being described with respect to one particular embodiment and as illustrative only. Those of ordinary skill in the art will appreciate that any term or terms with which these examples or illustrations are utilized will encompass other embodiments which may or may not be given therewith or elsewhere in the specification and all such embodiments are intended to be included within the scope of that term or terms. Language designating such nonlimiting examples and illustrations includes, but is not limited to: “for example,” “for instance,” “e.g.,” “in one embodiment.”

Embodiments described herein disclose a holder being configured to couple with a portable electronic device and interface with one or more fingers of a user's hand. If the holder is interfaced with the user's finger, then the user may interact with inputs of the portable electronic device (e.g. with the user's thumb), while the electronic device is secured to the holder.

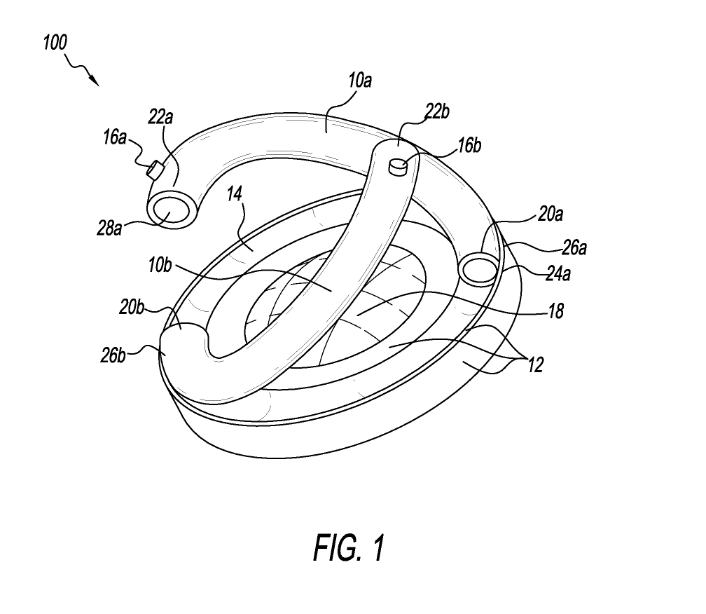

FIG. 1 depicts an embodiment of a portable electronic device holder 100. Portable electronic device holder 100 be substantially ring-shaped, and may be configured to be worn around a user's finger.

Holder 100 may include body 12, first half-ring 10A, second half-ring 10B, and push button 18.

Body 12 may include a curved outer edge with a channel 14 being disposed along the circumference of body 12. Channel 14 may be positioned adjacent to or substantially adjacent to the curved outer edge of body 12. Channel 14 may be a groove, depression, etc. that is concave in shape, and may be configured to receive first half-ring 10A and second half-ring 10B. If first half-ring 10A and second half-ring 10B are in a first position being disposed within channel 14, then corresponding ends of first half-ring 10A and second half-ring 10B may be positioned adjacent to each other to form a ring within channel 14.

First half-ring 10A and second half-ring 10B may be curved and substantially tubular in shape. In embodiments, if first half-ring 10A and second half-ring 10B are in the first position, then first half-ring 10A and second half-ring 10B may be configured to be disposed within channel 14. First half-ring 10A and second half-ring 10B may also be dynamic elements that are configured to rotate in opposite directions to project away from body 12 to from a ring-hook in a second position. If first half-ring 10A and second half-ring 10B are disposed in the second position, a first end of first half-ring 10A may be positioned on a first side of channel 14 and a first end of second half-ring 10B may be positioned on a second side of channel 14, and a second end of first half-ring 10A and second half-ring 10B may be coupled together in a position vertically aligned with the center of body 12.

First half-ring 10A and second half-ring 10B may include hinged edges 20A and 20B, pivots 24A and 24B, swing limiters 26A and 26B, magnetic edges 22A and 22B, and pads 16A and 16B, respectively.

Hinged edges 20A and 20B may be positioned on first ends of first half-ring 10A and second half-ring 10B, respectfully. Hinged edges 20A and 20B may be configured to allow first half-ring 10A and second half-ring 10B to rotate around pivots 24A and 24B. In embodiments, pivots 24A and 24B may be projections coupling hinged edges 20A and 20B, respectively, and body 12.

Swing limiters 26A and 26B may be cut-outs or indentations within hinged edges 20A and 20B, to limit the amount of rotation of first half-ring 10A and second half-ring 10B, respectively. Swing limiters 26A and 26B may be configured to limit the rotation of first half-ring 10A and second half-ring 10B such that as first half-ring 10A and second half-ring 10B rotate around pivots 24A and 24B, first half-ring 10A and second half-ring 10B may move from the first position to the second position without rotating past the second position.

Magnetic edges 22A and 22B may be positioned on second ends of first half-ring 10A and second half-ring 10B, respectfully. Magnetic edges 22A and 22B may have magnets 28A with opposite polarities that may be configured to couple with each other to secure first half-ring 10A and second half-ring 10B together. In embodiments, if first half-ring 10A and second half-ring 10B are in the second position, then magnetic edge 22A and magnetic edge 22B may be positioned adjacent to each other, such that first half-ring 10A and second half-ring 10B may be coupled by magnets 28A. In other embodiments, one edge may include a magnet and the other may include ferromagnetic material. In further embodiments, the two half-rings may be coupled, at their ends or elsewhere, by any fastener, such as a clip, hook-and-loop, or other mechanical fastener.

Pads 16A and 16B may be projections positioned on first half-ring 10A and second half-ring 10B, respectfully, that are configured to receive force to rotate first half-ring 10A and second half-ring 10B. Pads 16A and 16B may be positioned in close proximity to second ends of first half-ring 10A and second half-ring 10B. Projections 16A and 16B may be configured to receive pressure to rotate first half-ring 10A and second half-ring 10B to move first half-ring 10A and second half-ring 10B from the first position to the second position, and/or from the second position to the first position. As half-rings 10A, 10B may be rounded and metallic, and therefore low-friction, pads 16A, 16B provide a highly frictious point of contact for ease of engagement with a user's fingers, and of rotation.

Push button 18 may be a button disposed on a first surface of holder 100. Push button 18 may be disposed within an inner circumference formed by first half-ring 10A and second half-ring 10B when first half-ring 10A and second half-ring 10B are in the first position. Push button 18 may be configured to operate a vacuum device (not shown) positioned on a second, opposite surface of holder 100. The vacuum device may be configured such that when the vacuum device is pressed against a surface with the push button 18 in the depressed position, the push button 18 is forced up, generating a strong negative pressure between the surface and the holder 100. The negative pressure of air may create a vacuum or a partial vacuum to couple with or adhere to the surface or backing of a portable electronic device. One skilled in the art will appreciate that in other embodiments the vacuum device may be any device configured to secure a portable electronic device to the second surface of body 12, such as a regular suction cup, adhesive, clip, or the like. In embodiments, the vacuum device may be configured to removably couple the portable electronic device to body 12, such that the portable electronic device may be secured to body 12 in a first instance, and then selectively removed from body 12 in a second instance.

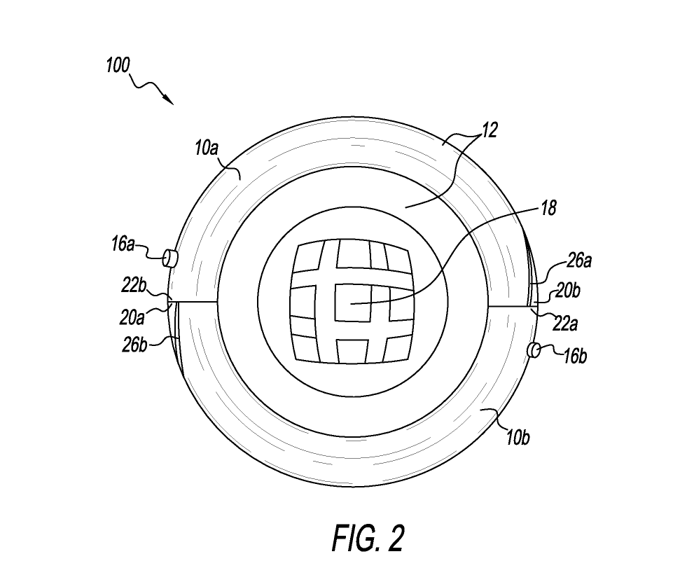

FIG. 2 depicts a top view of portable electronic device holder 100, according to one embodiment.

As depicted in FIG. 2, first half-ring 10A and second half-ring 10B are disposed in the first position, and at least a portion of first half-ring 10A and second half-ring 10B are disposed within channel 14. By first half-ring 10A and second half-ring 10B being dynamic and movable elements, when first half-ring 10A and second half-ring are disposed in the first position portable electronic device holder 100 may be configured to be a compact device to conserve space. This may greatly ease insertion of an attached device into and removal of an attached device from a pocket or other confined space. The curved upper surface of the half-rings and curved top of push button 18 also aid in this, as does the use of low-friction materials such as metal and smooth plastics. The use of recesses in particular reduces height of the holder when not in use (such as when stored in a pocket) while permitting a reasonable body-height, making possible the use of an effective push-button vacuum fastener. However in alternative embodiments there may be no recesses, and optionally the half-rings may be positioned between first and second surfaces of the body, around its periphery, to achieve similar height-reduction.

Further, while first ring 10A and second ring 10B are in the first position, magnetic edges 22A and 22B on the seconds ends of first ring 10A and second ring 10B may be configured to couple with magnets disposed on the first ends of second ring 10B and first ring 10A, respectively. While the magnetic edges 22A and 22B are coupled with magnets (or other ferromagnetic material) disposed on the first ends of second ring 10B and first ring 10A, first ring 10A and second ring 10B may be secured in the first position forming a full ring.

As further depicted in FIG. 2, if first half-ring 10A and second half-ring 10B are disposed in the first position, then pads 16A and 16B may project away from first half-ring 10A, second half-ring 10B and channel 14 such that a user may more easily and effectively rotate first half-ring 10A and/or second half-ring 10B.

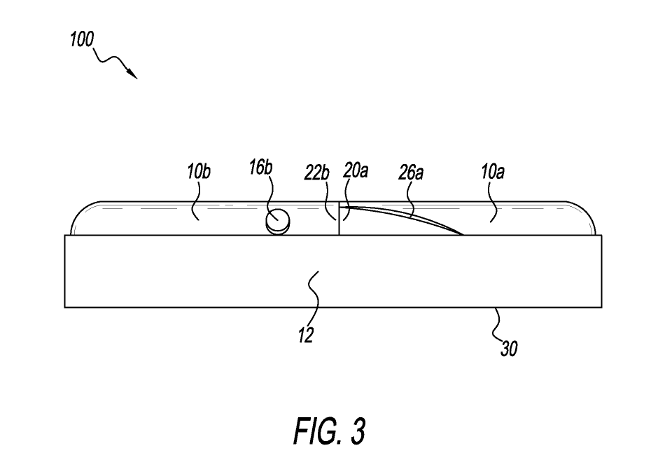

FIG. 3 depicts a side view of portable electronic device holder 100 with first half-ring 10A and second half-ring 10B being in the first position. If first half-ring 10A and second half-ring 10B are in the first position, then portable electronic device holder 100 may be a compact, unified device.

Furthermore, FIG. 3 shows vacuum device 30 positioned on a first surface of portable electronic device holder 100. In embodiments, vacuum device 30 may be a gasket or any other type of mechanical seal that fills that space between two or more mating surface, wherein a first mating surface corresponds to portable electronic device holder 100 and a second mating surface corresponds to the electronic device. Vacuum device 30 may mechanically force depressed pushbutton 18 upwards when pressed against a surface to create a powerful seal.

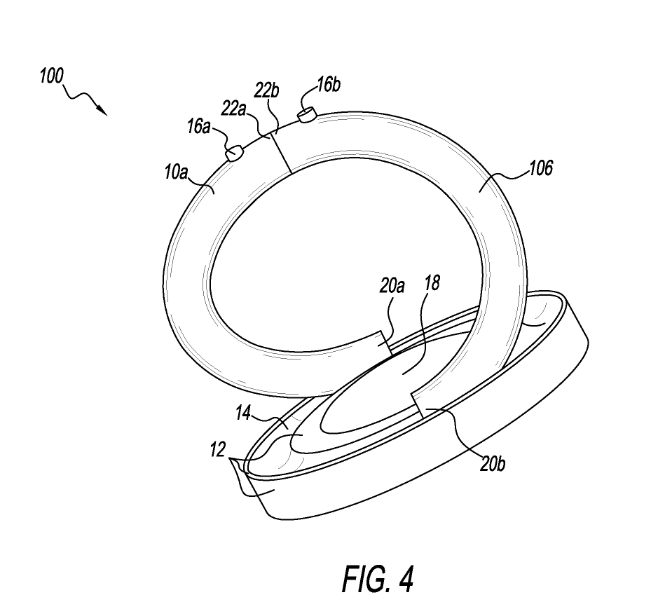

FIG. 4 depicts a perspective view of portable electronic device holder 100 with first half-ring 10A and second half-ring 10B being in the second position, according to one embodiment.

As depicted in FIG. 4, if first half-ring 10A and second half-ring 10B are in the second position, first half-ring 10A and second half-ring 10B may form a unified ring-hook extending from a first side of body 12 to a second side of body 12. In embodiments, the unified ring-hook may be comprised of the first half-ring 10A and second half-ring 10B rotated upward to vertically project away from body 12.

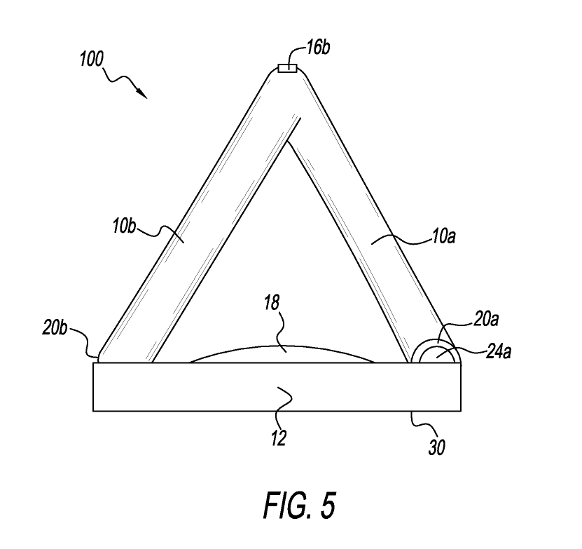

FIG. 5 depicts a side view of portable electronic device holder 100 with first half-ring 10A and second half-ring 10B being in the second position, according to one embodiment.

As depicted in FIG. 5, if first half-ring 10A and second half-ring 10B are in the second position, the second ends of first half-ring 10A and second half-ring 10B may interface with each other in a position that is vertically alighted with the center of body 12. Furthermore, when first half-ring 10A and second half-ring 10B are in the second position, hinged edges 20A and 20B may be rotated around pivots 24A and 24B to project first half-ring 10A and second half-ring 10B away from body 12.

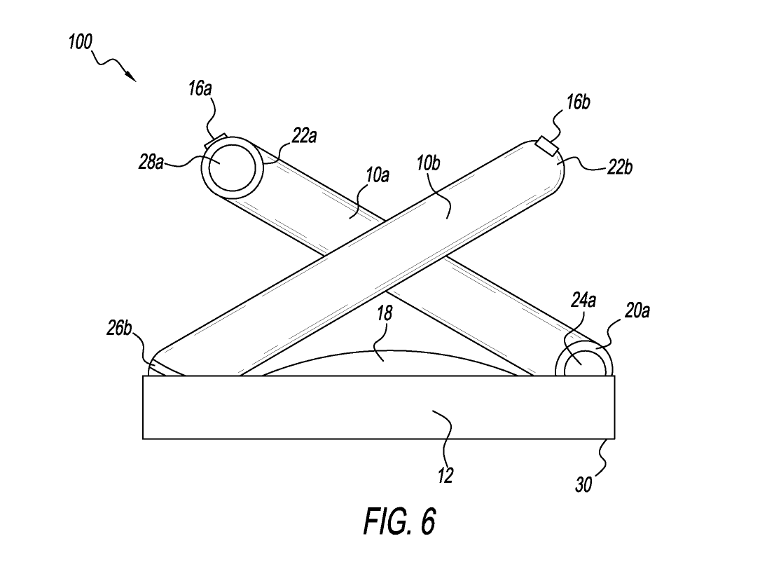

FIG. 6 depicts an embodiment of a side view of portable electronic device holder 100 with first half-ring 10A and second half-ring 10B disposed in a position between the first position and the second position. As first half-ring 10A and second half-ring 10B are being rotated from the first position to the second position, the first half-ring 10A and the second half-ring may 10B be in a position perpendicular to each other, where the height of the second ends of first half-ring 10A and second half-ring 10B is less than when the first half-ring 10A and second half-ring 10B are in second position and greater than when first half-ring 10A and second half-ring 10B are in the first position.

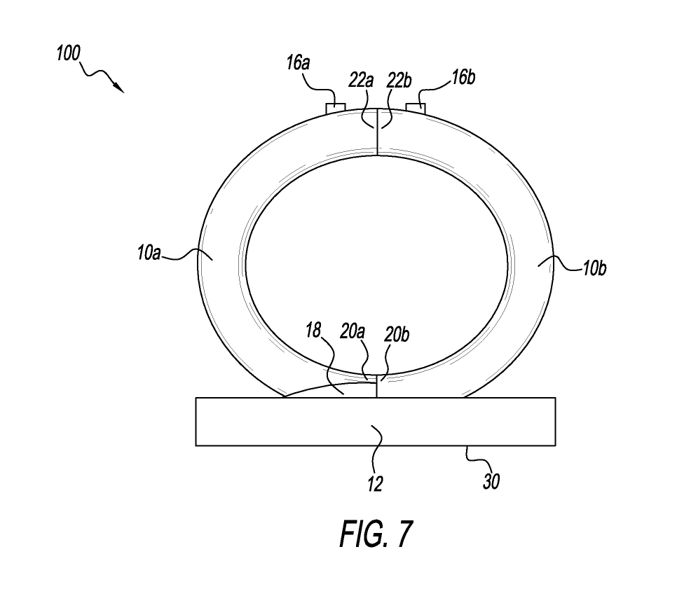

FIG. 7 depicts a side view of portable electronic device holder 100 with first half-ring 10A and second half-ring 10B being in the second position, according to one embodiment. As depicted in FIG. 7, if first half-ring 10A and second half-ring 10B are in the second position, first half-ring 10A and second half-ring 10B together may form a helical shape extending from the first side of body 12 to the second side of body 12.

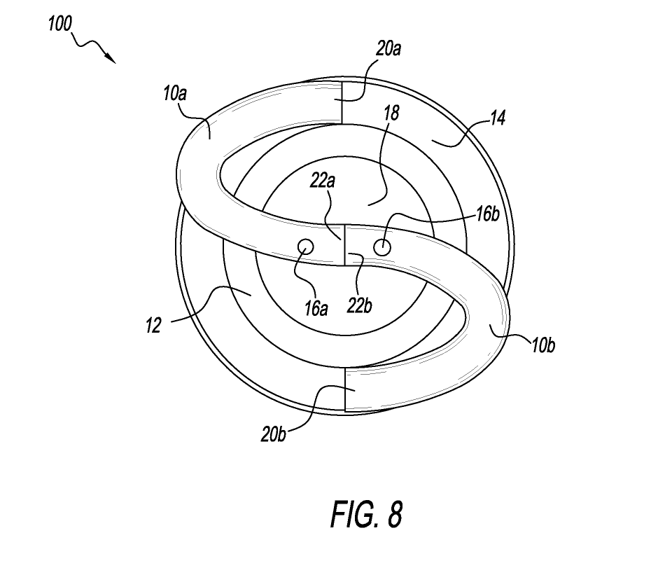

FIG. 8 depicts a top view of portable electronic device holder 100 with first half-ring 10A and second half-ring 10B being in the second position, according to one embodiment.

As depicted in FIG. 8, if first half-ring 10A and second half-ring 10B are in the second position, first half-ring 10A and second half-ring 10B may have a side profile that forms a ring, where a user's finger may be inserted.

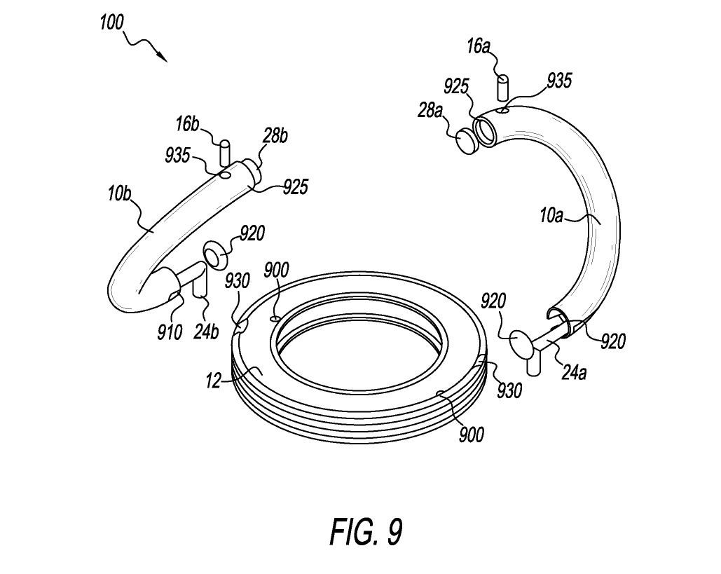

FIG. 9 depicts an exploded view of body 12 of electronic device holder 100, according to one embodiment. As depicted in FIG. 9, body 12 may include indentations 900 that are configured to receive pivots 24A and 24B. Responsive to pivots 24A and 24B being disposed within indentations 900 and within hinged edges 20A and 20B, respectively, first half-ring 10A and second half-ring 10B may rotate about pivots 24A and 24B.

As depicted in FIG. 9, first ends 910 of first half-ring 10A and second half-ring 10B may be covered by magnetic caps 920 and second ends 925 of first half-ring 10A and second half-ring 10B may include magnetic caps 28A and 28B, respectively. If first half-ring 10A and second half-ring 10B are disposed in the first position, then first ends 910 may be configured to magnetically couple with magnetic caps 28A and 28B to secure first half-ring 10A and second half-ring in the first position.

Pads 16A and 16B may be configured to be inserted into slots 935 in close proximity to second ends 920 of first half-ring 10A and second half-ring 10B. Outer surface of body 12 may include indentations 930 configured to receive pads 16A and 16B if first half-ring 10A and second half-ring 10B are in the first position. In embodiments, pads 16A and 16B may be placed within indentations 930 such that a user may easily access pad 16A or 16B to rotate first half-ring 10A or second half-ring 10B, respectively, into the second position.

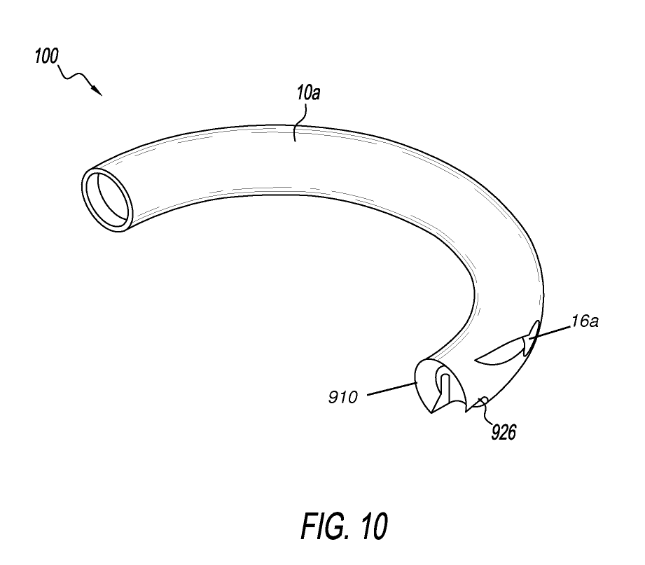

FIG. 10 depicts first half-ring 10A according to one embodiment without pad 16A, magnetic cap 28, or magnetic cap 920. As depicted in FIG. 10, half-ring 10A may include swing limiter 926. Swing limiter 926 may be a cut out or removed portion of first half-ring 10A. The vertical post portion of pivot 24A may sit within this cut-out. Swing limiter 926 may be sized such that half-ring 10A is configured to rotate upwards to a limit where first half-ring 10A is in the second position, but not beyond the limit. Any attempt to rotate the half-ring beyond this point will cause pivot 24A to contact the edge of the cut-out forming swing limiter 926 and prevent further movement. As such, swing limiter 926 may be configured to allow first half-ring 10A to rotate from the first position to the second position, but not further than the second position.

Although half-rings have been used as an exemplary embodiment, the invention is not limited to such embodiments. Any body shape may be used and the rotating elements may accordingly match the periphery of the body and therefore not be half-rings. For example, a square body could have half-square elements, a diamond-shaped body half-diamonds, etc. Further, in some embodiments the rotating elements may not lay along the periphery of the body when in their first position. In embodiments, the rotating elements need not be tubular, or any particular shape or cross-section.

In the foregoing specification, embodiments have been described with reference to specific embodiments. However, one of ordinary skill in the art appreciates that various modifications and changes can be made without departing from the scope of the invention. Accordingly, the specification and figures are to be regarded in an illustrative rather than a restrictive sense, and all such modifications are intended to be included within the scope of invention.

Although the invention has been described with respect to specific embodiments thereof, these embodiments are merely illustrative, and not restrictive of the invention. The description herein of illustrated embodiments of the invention is not intended to be exhaustive or to limit the invention to the precise forms disclosed herein (and in particular, the inclusion of any particular embodiment, feature or function is not intended to limit the scope of the invention to such embodiment, feature or function). Rather, the description is intended to describe illustrative embodiments, features and functions in order to provide a person of ordinary skill in the art context to understand the invention without limiting the invention to any particularly described embodiment, feature or function. While specific embodiments of, and examples for, the invention are described herein for illustrative purposes only, various equivalent modifications are possible within the spirit and scope of the invention, as those skilled in the relevant art will recognize and appreciate. As indicated, these modifications may be made to the invention in light of the foregoing description of illustrated embodiments of the invention and are to be included within the spirit and scope of the invention. Thus, while the invention has been described herein with reference to particular embodiments thereof, a latitude of modification, various changes and substitutions are intended in the foregoing disclosures, and it will be appreciated that in some instances some features of embodiments of the invention will be employed without a corresponding use of other features without departing from the scope and spirit of the invention as set forth. Therefore, many modifications may be made to adapt a particular situation or material to the essential scope and spirit of the invention.

In the description herein, numerous specific details are provided, such as examples of components and/or methods, to provide a thorough understanding of embodiments of the invention. One skilled in the relevant art will recognize, however, that an embodiment may be able to be practiced without one or more of the specific details, or with other apparatus, systems, assemblies, methods, components, materials, parts, and/or the like. In other instances, well-known structures, components, systems, materials, or operations are not specifically shown or described in detail to avoid obscuring aspects of embodiments of the invention. While the invention may be illustrated by using a particular embodiment, this is not and does not limit the invention to any particular embodiment and a person of ordinary skill in the art will recognize that additional embodiments are readily understandable and are a part of this invention.

It will also be appreciated that one or more of the elements depicted in the drawings/figures can also be implemented in a more separated or integrated manner, or even removed or rendered as inoperable in certain cases, as is useful in accordance with a particular application. Additionally, any signal arrows in the drawings/figures should be considered only as exemplary, and not limiting, unless otherwise specifically noted.

Benefits, other advantages, and solutions to problems have been described above with regard to specific embodiments. However, the benefits, advantages, solutions to problems, and any component(s) that may cause any benefit, advantage, or solution to occur or become more pronounced are not to be construed as a critical, required, or essential feature or component.

What I claim is:

1. A portable electronic device holder comprising:
a body including a first surface and a second surface and having a periphery, wherein the first surface is configured to attach to a device; and
a first element and a second element, each attached to the body and configured to be disposed in a first position, in which the element is parallel with the body, and to be disposed in a second position, in which the element projects away from the second surface;
wherein the first element and second element are configured, when both are in the second position, to form a closed path together with the body, wherein a finger can be inserted through the closed path to secure the finger to an attached device.

2. The portable electronic device holder of claim 1, wherein a first end of the first element is positioned adjacent to a second end of the second element and a first end of the second element is positioned adjacent to a second end of the first element when the first and second elements are both in the first position.

3. The portable electronic device holder of claim 2, wherein the first end of the first element is positioned adjacent to the first end of the second element when the first and second elements are both in the second position.

4. The portable electronic device holder of claim 1, wherein the first element and the second element are configured to rotate away from the body to move from the first position to the second position.

5. The portable electronic device holder of claim 3, wherein the first end of the first element is configured to couple with the first end of the second element in a position vertically aligned with a center of the body when the first and second elements are both in the second position.

6. The portable electronic device holder of claim 4, wherein the first end of the first element includes a first ferromagnetic material and the first end of the second element includes a second ferromagnetic material, such that the first ferromagnetic material and the second ferromagnetic material are attracted to each other.

7. The portable electronic device holder of claim 11, wherein the body is circular and the first and second elements are half-rings.

8. The portable electronic device holder of claim 4, wherein the first element is configured to rotate in a first direction and the second element is configured to rotate in a second direction when moving from the first position to the second position.

9. The portable electronic device holder of claim 1, wherein the first and second elements extend, in the first position, along the periphery of the body.

10. The portable electronic device holder of claim 9, wherein the first and second elements extend, in the first position, along the entire periphery of the body.

11. The portable electronic device holder of claim 10, wherein each of the first and second elements extends, in the first position, halfway around the periphery of the body.

12. The portable electronic device holder of claim 1, wherein the closed path has a curved inner edge such that, viewed straight through its central axis, the opening defined by the inner edge appears to be oval or elliptical.

13. The portable electronic device holder of claim 1, wherein each of the first and second elements comprises a projection on one end to provide a frictious contact point by which the element can be moved from the first position to the second position.

14. The portable electronic device holder of claim 1, wherein the body further comprises a recess, wherein the first and second elements are in the recess when in the first position, thereby reducing the height the first and second elements extend above the body in the first position.

15. The portable electronic device holder of claim 4, further comprising swing limiters that prevent rotation of the first and second elements past the second position.

16. A portable electronic device holder method, comprising:
attaching a portable electronic device holder to a device, wherein the portable electronic device holder comprises:
a body including a first surface and a second surface and having a periphery, wherein the first surface is configured to attach to a device; and
a first element and a second element, each attached to the body and configured to be disposed in a first position, in which the element is parallel with the body, and to be disposed in a second position, in which the element projects away from the second surface;
wherein the first element and second element are configured, when both are in the second position, to form a closed path together with the body, wherein a finger can be inserted through the closed path to secure the finger to an attached device;
moving the first and second elements from the first position to the second position; and
inserting one or more fingers through the closed path.

17. The method of claim 16, wherein moving the first and second elements from the first position to the second position comprises manipulating one end of each of the first and second elements and rotating the first and second elements in opposite directions.

18. A portable electronic device holder method, comprising:
providing a body including a first surface and a second surface and having a periphery, wherein the first surface is configured to attach to a device; and
attaching a first element and a second element to the body and configuring each element to be disposed in a first position, in which the element is parallel with the body, and to be disposed in a second position, in which the element projects away from the second surface; and
configuring the first element and second element, when both are in the second position, to form a closed path together with the body, wherein a finger can be inserted through the closed path to secure the finger to an attached device.

19. The method of claim 18, further comprising providing a recess in the body configured such that the first and second elements are in the recess when in the first position, thereby reducing a height the first and second elements extend above the body in the first position.

20. The method of claim 18, further comprising providing swing limiters on the body that prevent rotation of the first and second elements past the second position.
